(19) United States
(12) Patent Application Publication
(10) Pub. No.: US 2002/0042208 A1
(43) Pub. Date: Apr. 11, 2002

(54) Polishing liquid and method for structuring metal oxides

(76) Inventors: Gerhard Beitel, Muhldorf/Inn (DE); Eugen Unger, Augsburg (DE); Annette Sanger, Dresden (DE)

Correspondence Address: LERNER AND GREENBERG, P.A., Post Office Box 2480, Hollywood, FL, 33022-2480, US

(21) Appl. No.: 09/845,410

(22) Filed: Apr. 30, 2001

(30) Foreign Application Priority Data
Apr. 28, 2000 (DE) 100 22 649.3

(51) Int. Cl. H01L 21/302; H01L 21/461

(52) U.S. Cl. 438/745

(57) ABSTRACT

A polishing liquid is described for a chemical mechanical polishing process step. The polishing liquid contains at least one additive from the class of phase transfer catalysts, with which the rate of removal of metal oxides, in particular iridium oxide, can be increased. Moreover, the additive causes an increase in the ratio of removal rates between iridium oxide and silicon oxide, i.e. in the selectivity, which makes possible the structuring of iridium oxide layers using an oxide mask and a CMP process.

### BACKGROUND OF THE INVENTION

1. Field of the Invention

The invention concerns a polishing liquid which is suitable, for example, for the planarization and/or structuring of metal oxide layers on a substrate using a chemical mechanical polishing process step. The invention also concerns a method for planarization and/or structuring of metal oxides, in particular of iridium oxide.

In order to enable the charge stored in a storage capacitor of a memory cell to be read out reliably, the capacitance of the capacitor should have a value of at least approximately 30 fF. At the same time, the development of dynamic random access memory (DRAM) cells demands that the lateral extent of the capacitor be continuously reduced in order to achieve further increases in memory densities. These intrinsically contradictory demands on the memory cell capacitor lead to increasing complexity in the structuring of the capacitor (“trench capacitors”, “stack capacitors”, “crown capacitors”). Accordingly, the fabrication of the capacitor becomes more complicated and therefore more and more costly.

A different way of ensuring adequate capacities of the storage capacitors is to use materials with very high dielectric constants between the electrodes of the capacitor. This is the reason for the recent trend to replace the silicon oxide/silicon nitride dielectrics of the prior art with new materials, especially high-∈ paraelectric and ferroelectric materials, which have significantly higher relative dielectric constants (>20) than the conventional silicon oxide/silicon nitride (<8). As a result, the same capacitance can be attained with a much lower capacitor surface area and therefore much less complexity in the structuring of the capacitor. Important examples from these classes of materials used in practice are barium strontium titanate (BST, (Ba,Sr)TiO₃), lead zirconate titanate (PZT, Pb(Zr,Ti)O₃) and lanthanum doped lead zirconate titanate or strontium bismuth tantalate (SBT, SrBi₂Ta₂O₉).

In addition to DRAM modules known in the prior art, ferroelectric memory configurations, so-called FRAMs, will play an important role in the future. Compared with memory configurations of the prior art such as DRAMs and SRAMs, ferroelectric memory configurations have the advantage that the stored information is not lost as a result of an interruption to the voltage or power supply, but remains stored. The non-volatility of ferroelectric memory configurations derives from the fact that the polarization of ferroelectric materials induced by an external electric field is essentially retained even after the external electric field is switched off. The new materials mentioned above such as lead zirconate titanate (PZT, Pb(Zr,Ti)O₃), lanthanum doped lead zirconate titanate or strontium bismuth tantalate (SBT, SrBi₂Ta₂O₉) are also used for ferroelectric memory configurations.

Unfortunately, the use of the new paraelectric or ferroelectric materials requires the use of new electrode and barrier materials. The new paraelectric and ferroelectric materials are usually deposited on already existing electrodes (bottom electrode). Processing is carried out at high temperatures at which the materials normally used for the capacitor electrodes, for example doped polysilicon, are easily oxidized and lose their conducting properties which would lead to failure of the memory cell.

Because of their high resistance to oxidation and/or to the formation of electrically conducting oxides, the 4d and 5d transition metals, especially noble metals such as Ru, Rh, Pd, Os, Pt and particularly Ir or IrO₂, are regarded as promising candidates for replacing doped silicon/polysilicon as materials for electrodes and barriers.

Unfortunately, the above electrode and barrier materials recently being used in integrated circuits belong to a class of materials that can be structured only with difficulty. Due to their chemical inertness they are difficult to etch so that even if “reactive” gases are used, the material removed consists predominantly or almost exclusively of the physical part of the etching. For example, up to now iridium oxide has generally been structured by a dry etching process. A major disadvantage of the method is the lack of selectivity due to the high physical fraction of the etching process. As a result, the erosion of the masks, which unavoidably have sloping edges, results in that only a low dimensional accuracy of the structures can be guaranteed. In addition, undesirable redeposition occurs on the substrate, on the mask or in the equipment used.

Moreover, these materials are also extremely resistant towards the use of so-called chemical mechanical polishing (CMP) processes. Standard CMP methods exist for the planarization and structuring of metal surfaces, for example for tungsten and copper, and also for materials used for the barrier layer such as Ti, TiN, Ta and TaN. CMP processes for the planarization of polysilicon, silicon oxide and silicon nitride continue to be state-of-the-art. However, the polishing liquids used in these processes are not suitable for the removal of noble metals. The problem of a CMP process for noble metals and their oxides, e.g. Pt, Ir or IrO₂ consists once again of their chemical inertness and resistance to oxidation.

### SUMMARY OF THE INVENTION

It is accordingly an object of the invention to provide a polishing liquid and a method for structuring metal oxides that overcome the above-mentioned disadvantages of the prior art devices and methods of this general type, which can be used for the planarization and structuring of metal oxides, especially iridium oxide, and which guarantees a sufficiently high rate of removal.

According to the invention a polishing liquid is provided, in particular for the removal and/or structuring of metal oxides, especially iridium oxide, through chemical mechanical polishing. The polishing liquid contains water, abrasive particles, and at least one additive from the class of phase transfer catalysts. In addition, the polishing liquid has a pH of at least 9.5.

According to the invention the polishing liquid contains at least one additive from the class of phase transfer catalysts, i.e. a chemical which initiates a chemical reaction between substances in different phases which cannot react on their own, or only weakly. Especially suitable as additives are quaternary ammonium, phosphonium and other onium compounds with large-volume organic residues (e.g. alkyl residues). As representatives of the quaternary ammonium compounds, tetramethylammonium hydroxide (TMAH) or N-(2-hydroxyethyl)-trimethylammonium hydroxide (choline hydroxide) are especially suitable. It is also preferred to use a tetra-alkyl phosphonium hydroxide as an additive. In this case the fraction of the additive in the polishing liquid is preferably between 0.02 and 0.5 mol/l (moles per liter). In this context it is preferred not to add the above substances as salt of the polishing liquid. The polishing liquid has a pH of at least 10, and preferably of at least 11.

As examples, the additive increases the polishing rate of an IrO₂ layer (activation) and reduces it at a silicon oxide layer (passivation). Without wishing to restrict themselves in any way, the inventors are of the opinion that this could be explained through absorption of the additive molecules on the surface of the metal oxide. A further possibility could relate to the absorption of the additive molecules on the abrasive particles, leading to a change in the polishing properties of these. The additive could also modify the wetting properties of the polishing liquid in such a way that there is an effect on the polishing rate. There is a direct connection between the concentration of the additive and the rate of removal of the silicon oxide and iridium oxide, so that the polishing rate and selectivity on the iridium oxide can be adjusted through varying the type and concentration of the additive in the polishing liquid. In structuring an IrO₂ layer it is therefore possible to work with a silicon oxide mask without this being significantly removed during the CMP process and losing its accuracy through the chamfered edges. The polishing liquid according to the invention has the further advantage that the abrasive particles are suspended in the liquid without the need to use stabilizers.

The particles in the polishing liquid are preferably nano-particles, i.e. particles with a mean diameter somewhat smaller than 1 μm. The particles preferably are formed of aluminum oxide, silicon oxide, CeO or TiO2. It is also preferred that the fraction of abrasive particles in the polishing liquid amounts to between 1 and 30 percent by weight.

According to the invention, a method is also provided for planarization and/or structuring of a metal oxide layer, in particular an iridium oxide layer. The method includes the steps of providing a substrate; applying a metal oxide layer to the substrate; preparing a polishing liquid formed of a mixture having a pH of at least 9.5 and containing water, abrasive particles, and at least one additive from a class of phase transfer catalysts; and performing at least one of planarizing and structuring the metal oxide layer in a chemical mechanical polishing process utilizing the polishing liquid.

In accordance with an added mode of the invention, there is the step of applying a mask to the substrate before application of the metal oxide layer.

In accordance with another mode of the invention, there is the step of forming the mask from silicon oxide or silicon nitride.

The method according to the invention has the advantage that electrodes and barriers for highly integrated DRAMs, including those made of metal oxides such as iridium oxide, can be structured by CMP steps and without dry etching. By choosing the right concentration of the phase transfer catalyst in the polishing liquid, it is also possible to set the selectivity between iridium oxide and silicon oxide sufficiently high that removal using a chemical mechanical polishing process practically stops as soon as the mask surface of the silicon oxide is reached. Ending the CMP process at this point produces the iridium oxide layer structured exactly as defined by the mask surface. As a result, geometrical distortions through chemical or mechanical attack of the silicon oxide masks is largely prevented.

Other features which are considered as characteristic for the invention are set forth in the appended claims.

Although the invention is illustrated and described herein as embodied in a polishing liquid and a method for structuring metal oxides, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1-7 are diagrammatic, sectional views of a method for structuring an iridium oxide layer according to the invention.

### DESCRIPTION OF THE PREFERRED EMBODIMENTS

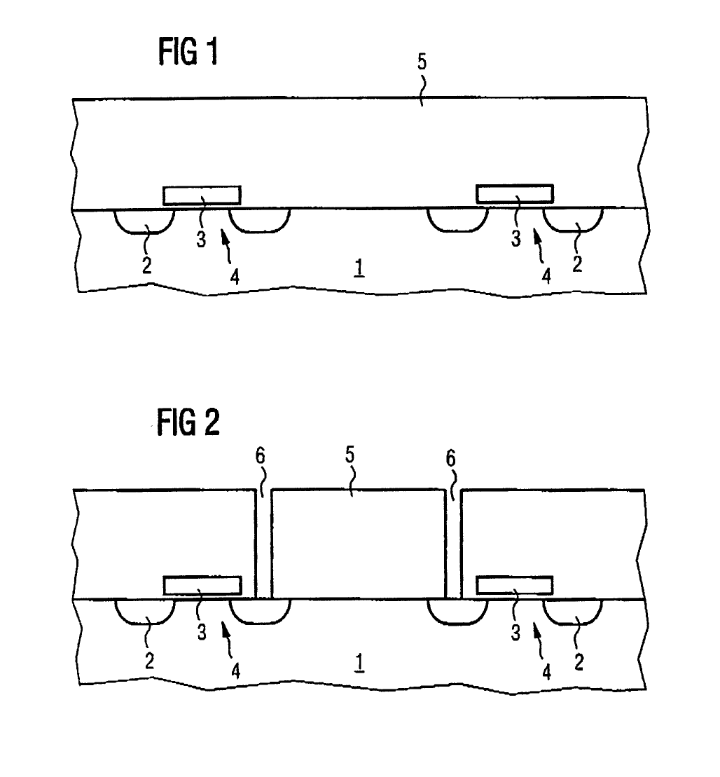

In all the figures of the drawing, sub-features and integral parts that correspond to one another bear the same reference symbol in each case. Referring now to the figures of the drawing in detail and first, particularly, to FIG. 1 thereof, there is shown a silicon substrate 1 prepared with finished field effect transistors 4, each of which has two diffusion zones 2 and one gate 3. Whereas the diffusion zones 2 and a transistor channel are disposed at a surface of the substrate 1, the gate 3 is separated from the channel by a gate oxide. The conductivity of the transistor channel between the two diffusion zones 2 can be controlled through the gate 3. In combination with storage capacitors yet to be fabricated, each of the transistors 4 forms a binary memory cell. The transistors 4 are produced by known state-of-the-art methods that are not discussed in detail here.

An insulating layer 5, for example a layer of SiO₂, is applied to the silicon substrate 1 with the transistors 4. Depending on the method used for the production of the transistors 4, several insulating layers can also be applied. The structure generated as a result is illustrated in FIG. 1.

Contact holes 6 are then produced by a photo-technique. The contact holes 6 provide a connection between the transistors 4 and the yet to be produced storage capacitors. The contact holes 6 are produced, for example, through anisotropic etching with fluorine-containing gases. The resulting structure is illustrated in FIG. 2.

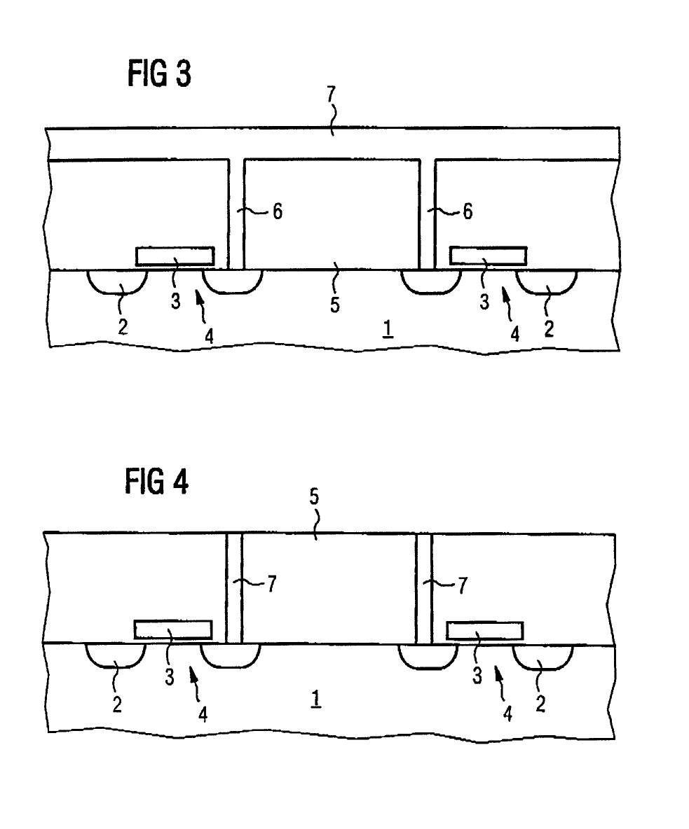

A conducting material 7, for example polysilicon doped in situ, is then applied to the structure. This can be performed, for example, using a chemical vapor deposition (CVD) method. Application of the conducting material 7 leads to a complete filling of the contact holes 6 and a continuous conducting layer is formed on the insulating layer 5 (see FIG. 3). The next process is a chemical mechanical polishing (CMP) step, which removes the continuous layer on the surface and produces an even surface. The only polysilicon that remains is in the contact holes 6 (see FIG. 4).

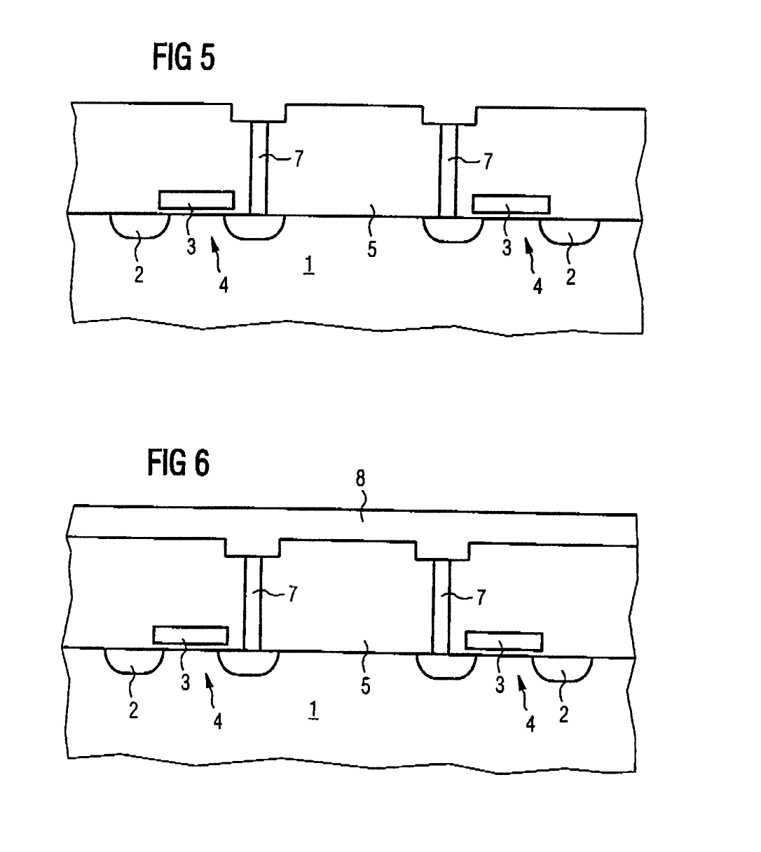

Next, photolithography is used to etch depressions in the insulating layer 5, overlapping the contact holes (see FIG. 5). Accordingly, a first step of the method according to the invention is complete and the substrate 1 has been prepared. Moreover, the insulating layer 5 with the depressions acts as a mask for structuring the yet to be produced iridium oxide barrier.

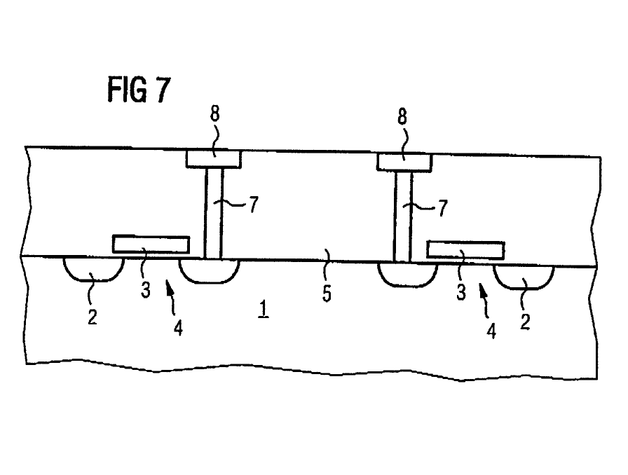

In order to fill the depressions in the silicon oxide 5 with IrO₂ as a barrier material, an IrO₂ layer 8 is first deposited on the entire surface of the substrate 1. The IrO₂ layer 8 can be produced, for example, by sputtering iridium in an atmosphere of oxygen (see FIG. 6). A CMP step follows with a polishing liquid according to the invention, with which the IrO₂ layer 8 is removed as far as the insulating layer 5, which serves as a mask (see FIG. 7). In this way the barriers are created above the polysilicon plugs. After the creation of the barriers a bottom electrode, a dielectric/ferroelectric layer and a top electrode are formed (not shown). Accordingly, a memory cell with a selecting transistor and a storage capacitor is produced. The metalization and passivation of the component can be performed subsequently using methods of prior art.

The polishing liquids according to the invention are described in the following.

Exemplary embodiment 1

Aqueous suspensions were prepared of SiO₂ nanoparticles in an ammoniacal solution. The SiO₂ fraction of these solutions was between 20 and 30 percent of the suspension by weight. The pH of the suspension lay between 9.5 and 10. Such suspensions are commercially available, for example under the name Klebosol 30N50. Tetramethylammonium hydroxide (TMAH) was then added to the suspension at a concentration of 0.05 to 0.5 mol/l.

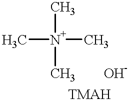

The addition of TMAH increased the pH of the suspension to values between 10 and 13. After this, no stabilizers or oxidizers are added to the suspension.

Table 1 shows a series of measurements that reveal how the removal rates of the polishing liquid on a silicon oxide layer and an iridium oxide layer depend on the concentration of the tetramethylammonium hydroxide. With increasing tetramethylammonium hydroxide concentration the removal rate of the iridium oxide increases while the removal rate of the TEOS silicon oxide drops. Thus increasing the concentration of iridium oxide enables both an increased removal rate of iridium oxide and an increased selectivity of removal to be achieved, as a result of which an iridium oxide layer can be precisely structured using a silicon oxide mask. A selectivity of 142:16 is ultimately attained at a concentration of 161 mmol/liter.

TABLE 1

| | | | Removal rate | Removal rate |
|---|---|---|---|---|
| | | Concentration | SiO₂ (TEOS) | (IrO₂) |
| Additive | pH | (mmol/l) | (nm/min) | (nm/min) |
| TMAH | 10.0 | 0 | 380 | 5 |
| TMAH | 11.0 | 41.2 | 287 | 65 |
| TMAH | 12.0 | 67 | 46 | 123 |
| TMAH | 12.7 | 161 | 16 | 142 |

Exemplary embodiment 2

Aqueous suspensions were prepared of SiO₂ nanoparticles in an ammoniacal solution. The SiO₂ fraction of these solutions was between 20 and 30 percent of the suspension by weight. The pH of the suspension lay between 9.5 and 10. N-(2-hydroxyethyl)-trimethylammonium hydroxide (choline hydroxide) was then added to the suspension at a concentration of 66 mmol/l.

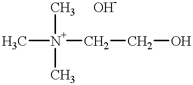

Choline hydroxide

The addition of N-(2-hydroxyethyl)-trimethylammonium hydroxide caused the pH of the suspension to increase to a value of 11.5. After this, no stabilizers or oxidizers were added to the suspension.

Table 2 shows a measurement illustrating the removal rates achieved by the polishing liquid prepared in this way on a silicon oxide layer and an iridium oxide layer.

TABLE 2

| | | | Removal rate | Removal rate |
|---|---|---|---|---|
| | | Concentration | SiO₂ (TEOS) | (IrO₂) |
| Additive | pH | (mmol/l) | (nm/min) | (nm/min) |
| Choline | 10.0 | 0 | 380 | 5 |
| Choline | 11.5 | 66 | 12 | 63 |

Comparative example

A further aqueous suspension of SiO₂ nanoparticles in an ammoniacal solution was prepared. The fraction of SiO₂ nanoparticles contained between 20 and 30 percent of the suspension by weight. The pH of the suspension lay between 9.5 and 10. To the suspension was then added potassium hydroxide (KOH) at a concentration of 80 mmol/l. The addition of KOH caused the pH to increase to a value of 11.3. After this, no stabilizers or oxidizers were added to the suspension.

Table 3 shows a measurement illustrating the removal rates achieved by the polishing liquid prepared in this way on a silicon oxide layer and an iridium oxide layer.

TABLE 3

| | | | Removal rate | Removal rate |
|---|---|---|---|---|
| | | Concentration | SiO₂ (TEOS) | (IrO₂) |
| Additive | pH | (mmol/l) | (nm/min) | (nm/min) |
| KOH | 10.0 | 0 | 380 | 5 |
| KOH | 11.3 | 80 | 461 | Approx. 0 |

From Table 3 it is apparent that an increase in the pH alone, through addition of KOH, does not increase the rate of removal of iridium oxide. On the contrary, the addition of KOH lowers the iridium oxide removal rate to a value below the measurable limit. On the other hand, the removal rate for silicon oxide is increased. Thus increasing the pH value without addition of the additive according to the invention did not lead to the hoped-for success.

Exemplary embodiment 3

An aqueous suspension of Al₂O₃ nanoparticles was prepared. The fraction of Al₂O₃ nanoparticles was between 1 and 5 percent of this suspension by weight. This kind of Al₂O₃ nanoparticles are commercially available, for example as aluminum oxide powder Type CR 30 from the company Baikowsky. Tetramethylammonium hydroxide (TMAH) was then added to the suspension at a concentration of 0.05 to 0.5 mol/l. The addition of the TMAH caused the pH of the suspension to increase to values between 10 and 13. After this, no stabilizers or oxidizers were added to the suspension.

Table 4 shows a measurement with TMAH as the additive. Once again, the TMAH increases the removal rate of iridium oxide and lowers it for silicon oxide. At a concentration of 140 mmol/l a selectivity of greater than 180:5 is achieved.

TABLE 4

| | | | Removal rate | Removal rate |
|---|---|---|---|---|
| | | Concentration | SiO₂ (TEOS) | (IrO₂) |
| Additive | pH | (mmol/l) | (nm/min) | (nm/min) |
| TMAH | 7.20 | 0 | | 10 |
| TMAH | 13 | 140 | 5 | >180 |

We claim:

1. A polishing liquid, comprising:
a mixture having a pH of at least 9.5 and containing:
water;
abrasive particles; and
at least one additive from a class of phase transfer catalysts.

2. The polishing liquid according to claim 1, wherein said abrasive particles have a diameter of less than 1 μm.

3. The polishing liquid according to claim 1, wherein said abrasive particles are formed from a material selected from the group consisting of aluminum oxide, silicon oxide, CeO and TiO₂.

4. The polishing liquid according to claim 1, wherein a fraction of said abrasive particles in said mixture amounts to between 1 and 30 percent by weight.

5. The polishing liquid according to claim 1, wherein a fraction of a phase transfer catalyst in the mixture amounts to between 0.02 and 0.5 mol/l.

6. The polishing liquid according to claim 1, wherein said additive is a quaternary ammonium compound.

7. The polishing liquid according to claim 6, wherein said additive includes tetramethylammonium hydroxide.

8. The polishing liquid according to claim 6, wherein said additive contains choline hydroxide.

9. The polishing liquid according to claim 1, wherein said mixture contains at least tetra-alkylphosphonium hydroxide as said additive.

10. The polishing liquid according to claim 1, wherein said mixture has a pH of at least 10.

11. The polishing liquid according to claim 1, wherein said mixture has a pH of at least 11.

12. The polishing liquid according to claim 1, wherein said mixture is configured for removing and structuring metal oxides, including iridium oxide, in a chemical mechanical polishing process.

13. A method for preparing a metal oxide layer, including an iridium oxide layer, which comprises the steps of:
providing a substrate;
applying a metal oxide layer to the substrate;
preparing a polishing liquid formed of a mixture having a pH of at least 9.5 and containing water, abrasive particles, and at least one additive from a class of phase transfer catalysts; and
performing at least one of planarizing and structuring the metal oxide layer in a chemical mechanical polishing process utilizing the polishing liquid.

14. The method according to claim 13, which comprises applying a mask to the substrate before application of the metal oxide layer.

15. The method according to claim 14, which comprises forming the mask from a material selected from the group consisting silicon oxide and silicon nitride.

16. A polishing liquid for at least one of removing and structuring of metal oxides, including iridium oxide, in a chemical mechanical polishing process, the polishing liquid comprising:
a mixture having a pH of at least 9.5 and containing:
water;
abrasive particles; and
at least one additive from a class of choline hydroxide and tetraalkylphosphonium salts.

17. The polishing liquid according to claim 16, wherein said abrasive particles have a diameter of less than 1 μm.

18. The polishing liquid according to claim 16, wherein said abrasive particles are formed of a material selected from the group consisting of aluminum oxide, silicon oxide, CeO and TiO₂.

19. The polishing liquid according to claim 16, wherein a fraction of said additive in said mixture amounts to between 0.02 and 0.5 mol/l.

20. The polishing liquid according to claim 16, wherein said mixture has a pH of at least 10.
